(19) United States
(12) Patent Application Publication
(10) Pub. No.: US 2025/0256953 A1
(43) Pub. Date: Aug. 14, 2025

(54) MICROELECTROMECHANICAL DEVICE FOR IMAGE SENSOR STABILIZATION PURPOSES

(71) Applicant: STMicroelectronics International N.V., Geneva (CH)

(72) Inventors: Roberto CARMINATI, Piancogno (BS) (IT); Manuel RIANI, Como (IT); Gabriele GATTERE, Castronno (Varese) (IT); Giacomo FERRARI, Broni (IT)

(73) Assignee: STMicroelectronics International N.V., Geneva (CH)

(21) Appl. No.: 19/047,134

(22) Filed: Feb. 6, 2025

(30) Foreign Application Priority Data
Feb. 12, 2024 (IT) 102024000002950

(51) Int. Cl. B81B 3/00; H04N 23/68

(52) U.S. Cl. CPC B81B 3/0018; H04N 23/687; B81B 2201/0292; B81B 2203/053; B81B 2207/07

(57) ABSTRACT

A microelectromechanical device includes a substrate, a platform suspended and movable with respect to the substrate, and actuators. The actuators are arranged on the substrate around the platform, coupled to respective coupling portions of the platform and having respective actuation axes parallel to the substrate and perpendicular to each other. The microelectromechanical device further includes connection structures, each coupling a respective actuator with the platform and comprising a motion conversion elastic element interposed between the respective actuator and the platform. Each motion conversion elastic element is configured to convert movements of the actuators along its corresponding actuation axes into movements of the coupling portions of the platform along directions transverse to the substrate.

### PRIORITY CLAIM

This application claims the priority benefit of Italian Application for Patent No. 102024000002950, filed on Feb. 12, 2024, the content of which is hereby incorporated by reference in its entirety to the maximum extent allowable by law.

### TECHNICAL FIELD

This disclosure relates to a microelectromechanical device for image sensor stabilization purposes.

### BACKGROUND

As is known, the stabilization of images generated by camera sensors, for example smartphone cameras, is an important operation in motion blur compensation systems, caused by the simple movement of the subject with respect to the camera, by out-of-focus conditions and physical limitations of the camera's optics such as diffraction and lens aberrations.

Optical Image Stabilization (OIS) and Sensor Shift Stabilization (SSS) are the two techniques currently used to maintain an image in focus at the same position on the sensor (known as “image sensor”): the first exploits movements of the lens barrel, while the second exploits the movements of the image sensor with respect to the camera lens barrel.

The sensor shift stabilization technique is the most widespread in the electronics of smart devices and generally takes into account at least two degrees of freedom (for example, an in-plane translation) for the movement of the support having the image sensor mounted thereon. Furthermore, a focus function may be implemented by introducing out-of-plane translations.

The commercially available and known solutions for stabilizers that implement sensor shift stabilization functions may comprise voice-coil-type actuators and flexures for moving the image sensor, or alternatively microelectromechanical (MEMS) actuators based on vertical comb electrodes. However, current solutions may have issues related to energy consumption and/or may be limited in the range of movement of the image sensor as they involve actuators that operate mainly out of plane.

There is a need in the art to overcome or at least partially mitigate the disadvantages and limitations of the state of the art.

### SUMMARY

In an embodiment, a microelectromechanical device includes a substrate and a platform that is suspended and movable relative to the substrate. The device has actuators arranged on the substrate around the platform, with each actuator coupled to a coupling portion of the platform. The actuators have respective actuation axes parallel to the substrate and perpendicular to each other. Connection structures are present, where each connection structure couples one of the actuators with the platform and includes a motion conversion elastic element interposed between that actuator and the platform. Each motion conversion elastic element converts movements of its associated actuator along its respective actuation axis into movements of the corresponding coupling portion of the platform along directions transverse to the substrate.

The platform may have a planar shape parallel to the substrate and may include pairs of two-by-two parallel sides. Each coupling portion may protrude from one of the sides of the platform, in a substantially central position, toward its associated actuator.

Each motion conversion elastic element may include a central portion dividing the motion conversion elastic element into two equal sides, with each side including an end portion and an intermediate portion. The end portions may be opposite to each other with respect to the central portion, with each intermediate portion disposed between the central portion and its associated end portion. A translation of the end portions parallel to the substrate may correspond to a rototranslation of the intermediate portions parallel to a plane perpendicular to the substrate, and a translation of the central portion perpendicular to the substrate.

Both end portions of each motion conversion elastic element may be connected to its associated actuator, and the central portion may be connected to its associated platform coupling portion by a motion transmission elastic element.

Each motion transmission elastic element may be configured to transmit a translation perpendicular to the substrate to its associated coupling portion, may be defined by a flat plate perpendicular to the substrate, and may be configured to twist.

Each motion conversion elastic element may include a first elastic body, a second elastic body, and multiple transverse elements. The first and second elastic bodies may be defined by flat rectangular plates, perpendicular to the substrate and offset from each other along both a direction parallel to the substrate, and a direction perpendicular to the substrate, such that the second elastic body is at a lower height relative to the substrate than the first elastic body. The transverse elements may be defined by flat rectangular plates perpendicular to the substrate, uniformly spaced from each other, and may have first sides connected to the first elastic body and second sides, opposite to the first sides, connected to the second elastic body.

The actuators may be organized in a first pair of actuators having a first actuation axis parallel to the substrate, and a second pair of actuators having a second actuation axis parallel to the substrate and perpendicular to the first actuation axis.

The device may include a control unit coupled to the actuators and configured to drive the actuators so that the platform performs at least one of the following movements or combination of movements: rotation around the first actuation axis, rotation around the second actuation axis, and translation parallel to a third actuation axis perpendicular to the substrate.

The device may include a control unit coupled to the actuators and configured to drive the actuators so that the platform performs at least one of the following movements or combination of movements: roll, pitch, and out-of-plane translation.

The control unit may be configured to drive the actuators of each of the first and second pairs of actuators in either a concordant manner or a discordant manner.

Each motion conversion elastic element may be coupled to its associated actuator and to the platform so that concordant driving of the first pair of actuators causes roll movements of the platform, concordant driving of the second pair of actuators causes pitch movements of the platform, and discordant driving of both the first and second pairs of actuators causes out-of-plane translation movements of the platform.

Each motion conversion elastic element may be coupled to its associated actuator and to the platform so that concordant driving of both the first and second pairs of actuators causes combined roll and pitch movements of the platform.

The platform may include a pair of sides parallel to the first actuation axis and a pair of sides parallel to the second actuation axis. The motion conversion elastic elements associated with the first pair of actuators may be arranged parallel to the second actuation axis, and the motion conversion elastic elements associated with the second pair of actuators may be arranged parallel to the first actuation axis.

Each connection structure may further include first elastic elements, first anchors fixed to the substrate, second elastic elements, and second anchors fixed to the substrate. The first elastic elements and first anchors of each connection structure may maintain the platform suspended with respect to the substrate. The second elastic elements and second anchors of each connection structure may allow movement of the associated actuator.

The first anchors of each connection structure may be arranged on opposite sides of the associated coupling portion of the platform. Each first elastic element may connect one of the first anchors to the associated coupling portion and may be yielding parallel to a direction perpendicular to the substrate. The second anchors of each connection structure may be arranged on opposite sides of the associated actuator. Each second elastic element may connect one of the second anchors to the associated actuator and may be yielding parallel to the substrate.

The actuators may be electrostatic linear actuators.

### BRIEF DESCRIPTION OF THE DRAWINGS

For a better understanding, preferred embodiments are presented, by way of non-limiting example, with reference to the attached drawings, wherein:

FIG. 1 schematically shows, in a top-plan view, a MEMS device;

FIG. 2 schematically shows an enlarged portion of the MEMS device of FIG. 1;

FIG. 3 schematically shows, in a cross-section, an enlarged portion of the MEMS device of FIG. 1;

FIG. 4 schematically shows the enlarged portion of FIG. 2 with elements removed;

FIG. 5 schematically shows, in a perspective view, a portion of an element of the MEMS device of FIG. 1;

FIGS. 6a-6c and 7a-7c schematically show, in respective cross-sections, the operating principle of the element of FIG. 5;

FIG. 8a schematically shows the portion of FIG. 4 in an operating condition of the MEMS device of FIG. 1;

FIGS. 8b and 8c schematically show, in the same cross-section, two distinct enlarged portions of the MEMS device of FIG. 1 in the operating condition of FIG. 8a;

FIG. 8d schematically shows, in the same cross-section as FIGS. 8b and 8c, the arrangement of an element of the MEMS device of FIG. 1 in the operating condition of FIG. 8a;

FIGS. 9a and 9b schematically show, in the same cross-section, two distinct enlarged portions of the MEMS device of FIG. 1 in a different operating condition;

FIG. 9c schematically shows, in the same cross-section as FIGS. 9a and 9b, the arrangement of an element of the MEMS device of FIG. 1 in the operating condition of FIGS. 9a and 9b;

FIG. 10 shows a simplified block diagram relating to the driving of the MEMS device of FIG. 1.

### DETAILED DESCRIPTION

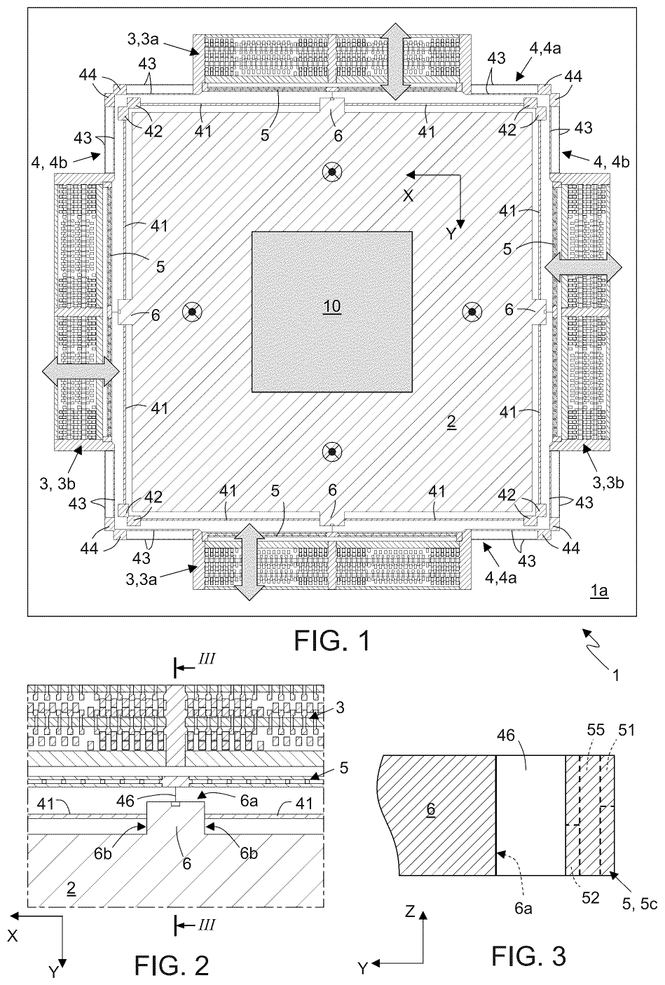

A stabilizer MEMS device (or simply “device”) 1 is shown in FIG. 1. The device 1 includes a substrate 1a, a platform 2 (or support), four actuators 3 arranged around the perimeter of the platform 2, and four respective connection structures 4, one for each actuator 3. The device 1 is configured to operate as a stabilizer of an image sensor 10, for example a camera image sensor, mounted on the platform 2. The image sensor 10 therefore follows movements imparted to the platform 2, which are described below. The device 1 is formed using semiconductor materials; for example, the substrate 1a and the platform 2 are made of silicon.

In detail, the platform 2 is suspended with respect to the substrate 1a and has a substantially rectangular shape in plan, and the four actuators 3 are arranged, each adjacent to a respective side of the platform 2. Each connection structure 4 couples a respective actuator 3 with a respective side of the platform 2. The platform 2 furthermore comprises four coupling portions 6, each protruding from a respective side of the platform 2 toward the respective actuator 3. In a non-limiting embodiment, each coupling portion 6 has a polygonal profile comprising three sides, wherein a transmission side 6a is transverse to two substantially parallel connection sides 6b, as shown in FIG. 2. Each coupling portion 6 protrudes from the respective side of the platform 2 in a substantially central position.

Considering a reference system of orthogonal axes X, Y, Z, the platform 2 has a substantially planar shape parallel to the XY plane. A first pair of actuators 3a comprises actuators 3 facing opposite sides of the platform 2 parallel to the X axis, and a second pair of actuators 3b comprises actuators 3 facing opposite sides of the platform 2 parallel to the Y axis. Actuators 3 of distinct pairs are therefore arranged, parallel to the XY plane, perpendicular to each other.

The platform 2 of the device 1 is operated by the actuators 3 to perform roll (rotation around the X axis), pitch (rotation around the Y axis) and out-of-plane translation (along the Z axis) movements, to compensate for image blur conditions in a closed-loop system. In FIG. 1, the device 1 is shown in a rest condition, i.e., when the platform 2 is not operated by any actuator 3. In a non-limiting embodiment, the platform 2 is positioned in the rest condition so that each side is equidistant from the respective actuator 3.

The actuators 3 of FIG. 1 are linear actuators of the “in-plane” type, i.e., actuators capable of imparting movements in a plane parallel to main faces of the platform 2 along respective actuation axes. Specifically, in the device 1, the first pair of actuators 3a has a first actuation axis parallel to the Y axis, while the second pair of actuators 3b has a second actuation axis parallel to the X axis. In more detail, the actuators 3 are electrostatic actuators, for example of a capacitive type, comprising fixed electrodes and movable electrodes interdigitated with each other. In FIG. 1, the actuators 3 of the first pair of actuators 3a comprise a plurality of rows of electrodes offset from each other along the Y axis, each row comprising a plurality of pairs of corresponding fixed electrodes—anchored to the substrate 1a—and movable electrodes offset from each other along the X axis. The actuators 3 of the second pair of actuators 3b comprise a plurality of rows of electrodes offset from each other along the X axis, each row comprising a plurality of pairs of corresponding fixed electrodes—anchored to the substrate 1a—and movable electrodes offset from each other along the Y axis.

The movements caused by the actuators 3 are transmitted to the platform 2 by the respective connection structures 4. In detail, and with reference also to the details of FIGS. 2 and 3, each connection structure 4 comprises: a pair of first elastic elements 41; a pair of first anchors 42 fixed to the substrate 1a; a pair of second elastic elements 43; a pair of second anchors 44 fixed to the substrate 1a; a motion conversion elastic element 5; and a motion transmission elastic element 46.

The first elastic elements 41 and the first anchors 42 of each connection structure 4 are configured to maintain the platform 2 suspended with respect to the substrate 1a. In particular, the first anchors 42 are arranged around the vertices of the platform 2. Each first elastic element 41 of the pair connects a respective first anchor 42 to the coupling portion 6 of the corresponding side of the platform 2. More particularly, the first elastic elements 41 are connected to the corresponding coupling portion 6 on opposite sides, i.e., each to a respective connection side 6b. Each first elastic element 41 of the device 1 comprises, for example, a flexure. In addition, the first elastic elements 41 of a respective pair are arranged on opposite sides of the corresponding coupling portion 6 so as to be aligned with each other.

The second elastic elements 43 and the second anchors 44 of each connection structure 4 are configured to allow the movements of the corresponding actuator 3. In particular, the second anchors 44 are arranged on opposite sides of the actuators 3 and are also arranged alongside respective first anchors 42 in more external positions with respect to the platform 2. Each second elastic element 43 of a respective pair connects a respective second anchor 44 to the corresponding actuator 3. More particularly, the second elastic elements 43, the second anchors 44, and the actuators 3 of the device 1 surround corresponding first elastic elements 41, first anchors 42, and coupling portions 6. Furthermore, the first anchors 42 and the second anchors 44 of each connection structure 4 are arranged respectively alongside a first anchor 42 and a second anchor 44 of the adjacent connection structure 4. Each second elastic element 43 of the device 1 comprises, for example, a pair of flexures which, in the rest condition, are parallel to each other. In addition, the second elastic elements 43 of a respective pair are arranged on opposite sides of the corresponding actuator 3 and aligned with each other.

Connection structures 4 corresponding to distinct pairs of actuators 3 are arranged, parallel to the XY plane, perpendicular to each other. A first pair of connection structures 4a, corresponding to the first pair of actuators 3a, and a second pair of connection structures 4b, corresponding to the second pair of actuators 3b, may therefore be identified. In detail, the first and second elastic elements 41, 43 of the first pair of connection structures 4a extend parallel to the X axis, and the first and second elastic elements 41, 43 of the second pair of connection structures 4b extend parallel to the Y axis. Even more in detail, the first elastic elements 41 of the device 1 are yielding with respect to the Z axis, i.e., for out-of-plane movements; the second elastic elements 43 of the device 1 are instead yielding for in-plane movements and are rigid for out-of-plane movements.

The motion conversion elastic elements 5 of each connection structure 4 are configured to convert the in-plane movements of the actuators 3 into the out-of-plane movements of the platform 2 previously described, i.e., into movements of the platform 2 along directions characterized by at least one component perpendicular to the substrate 1a. More precisely, the motion conversion elastic elements 5 are configured to convert the movements of the actuators 3 in the XY plane into corresponding movements of the respective coupling portions 6 along the Z axis. For example, the motion conversion elastic elements 5 may be formed substantially as described in U.S. Pat. No. 11,993,509 (corresponding to European Patent No. 3,872,451), in the name of the Applicant and incorporated by reference in its entirety. Hereinafter, for simplicity, reference will be made to only one of the motion conversion elastic elements 5 of the first pair of connection structures 4a and to the corresponding actuator 3. What has been stated also applies to the motion conversion elastic elements 5 of the second pair of connection structures 4b and to the respective actuators 3, taking into consideration the perpendicularity relationship in the arrangement of the actuators 3 and the connection structures 4 in the device 1 previously described.

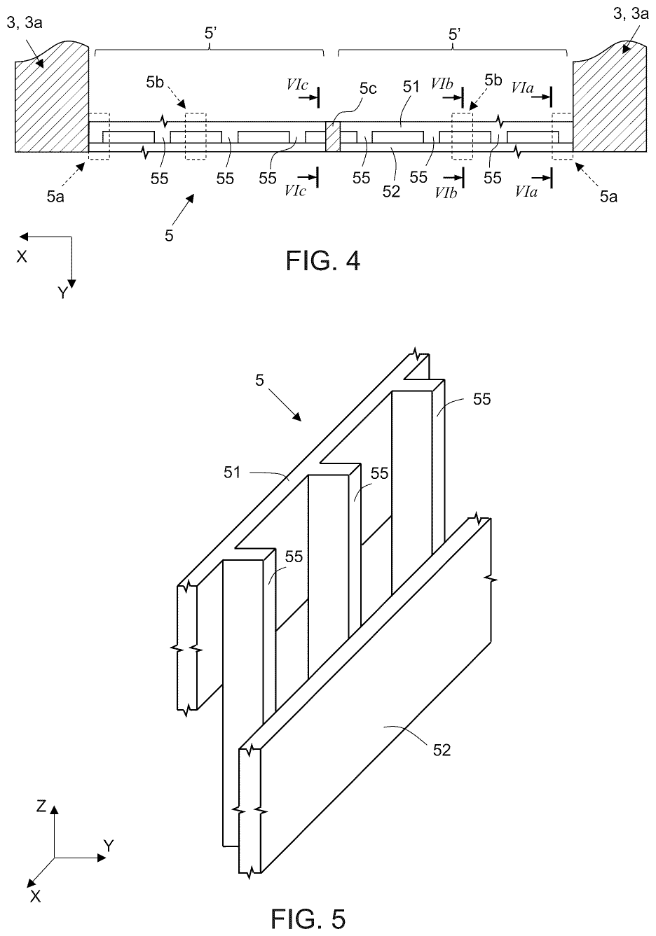

Also with reference to FIGS. 4 and 5, the motion conversion elastic element 5 comprises two end portions 5a and a central portion 5c. The two end portions 5a are opposite to each other along the X axis with respect to the central portion 5c. Furthermore, the central portion 5c divides the motion conversion elastic element 5 into two identical sides 5′, each comprising a respective end portion 5a and a respective intermediate portion 5b. Each intermediate portion 5b is arranged, on the respective side 5′, in a substantially median position between the central portion 5c and the respective end portion 5a. The motion conversion elastic element 5 is arranged parallel to the actuator 3, to which it is connected in positions corresponding to the two end portions 5a. The motion conversion elastic element 5 is also included between the actuator 3 and the respective pair of first elastic elements 41 (not shown in FIG. 4), so that the central portion 5c faces the respective coupling portion 6 of the platform 2. The central portion 5c is connected to the respective coupling portion 6 (see FIGS. 2 and 3) by the respective motion transmission elastic element 46, which is defined by a flat plate, for example rectangular, in the rest condition perpendicular to the X axis. The motion transmission elastic element 46 is connected to the transmission side 6a of the respective coupling portion 6. In the non-limiting embodiment of FIG. 1, furthermore, the motion conversion elastic element 5 is collinear with the second elastic elements 43 of the respective pair.

The motion conversion elastic element 5 comprises a first elastic body 51, a second elastic body 52, and a plurality of transverse elements 55, all of which are formed, for example, of the same semiconductor material as the substrate 1a and the platform 2 and form a single piece.

The first elastic body 51 and the second elastic body 52 are defined by flat rectangular plates of the same shape, in the rest condition perpendicular to the Y axis and elongated in the direction of the X axis. The first elastic body 51 and the second elastic body 52 are offset with respect to each other both in the direction of the Y axis and in the direction of the Z axis. For example, the first elastic body 51 extends adjacent to the actuator 3 and at a greater distance from the respective side of the platform 2; conversely, the second elastic body 52 extends adjacent to the respective side of the platform 2 and at a greater distance from the actuator 3. Furthermore, the second elastic body 52 is closer to the substrate 1a than the first elastic body 51. In a non-limiting embodiment, the central portion 5c is a joint section of the motion conversion elastic element 5 which joins the first and second elastic bodies 51, 52 and which is connected to the motion transmission elastic element 46 along the Z axis.

The transverse elements 55 are defined by flat plates of the same shape, for example rectangular, in the rest condition perpendicular to the X axis. The transverse elements 55 are uniformly spaced along the X axis and have first sides connected to the first elastic body 51 and second sides, opposite to the first sides, connected to the second elastic body 52.

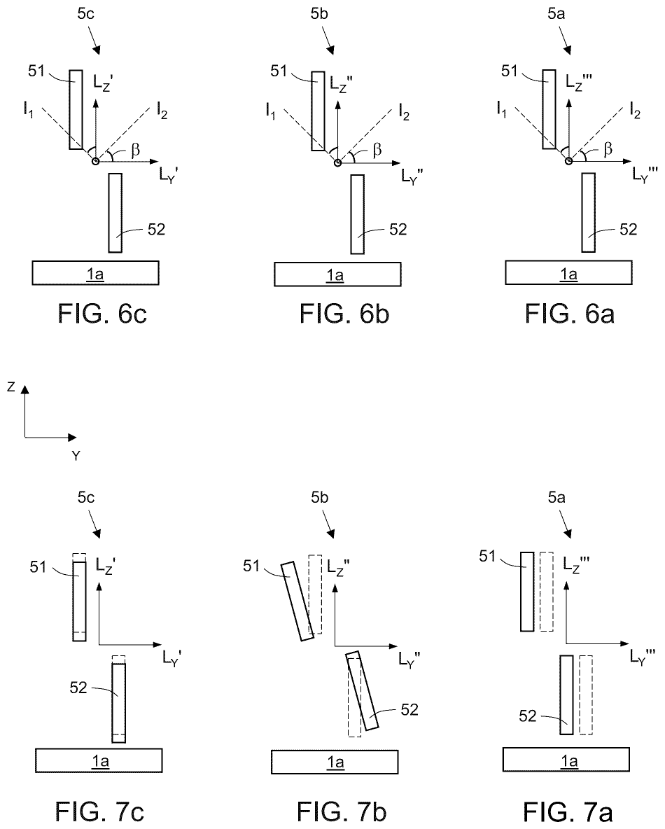

FIGS. 6a-6c show, by way of example, cross-sections of the motion conversion elastic element 5 along planes parallel to the YZ plane at an end portion 5a, at an intermediate portion 5b, and at the central portion 5c, respectively. In each of FIGS. 6a-6c, the main axes of inertia I1, I2 of the corresponding section of the motion conversion elastic element 5 are also shown, assuming that this section has infinitesimal thickness. In the rest condition, in particular, the main axes of inertia I1, I2 have the same orientation in each section and are misaligned and transverse with respect to both the Y axis and the Z axis. FIGS. 6a-6c also show, in rest conditions, pairs of local axes (indicated respectively by Ly′-Lz′, Ly″-Lz″ and Ly″-Lz″), each pair being formed by axes parallel to the Y axis and the Z axis, respectively, and passing through the barycenter of the section shown.

For each section of the motion conversion elastic element 25, a centrifugal moment of inertia Ic may be calculated, with respect to the corresponding pair of local axes, through the

$${I}_{C} = \int \int {r}_{1} {r}_{2} d A ,$$

where r1 and r2 represent the distance of each point of the section from first and second axes of the pair of local axes respectively, while dA is the area unit of the section. The centrifugal moment of inertia Ic is non-zero, since the local axes are not axes of symmetry of the section and therefore do not coincide with the main axes of inertia I1, I2. In particular, the main axes of inertia I1, I2 form an angle β with the local axis parallel to the Z axis and with the local axis parallel to the Y axis, respectively.

Consequently, as may be seen in FIGS. 7a-7c, a force applied on the motion conversion elastic element 5, for example along the local axis Lz″, causes a skew bending of the motion conversion elastic element 5. In particular, this force causes a deformation along the local axis Lz″, which results in a deformation along the local axis Ly″.

Compared to the rest positions, represented with a dashed line, for each side 5′ of the motion conversion elastic element 5, in response to a same translation of the end portion 5a in the direction of the Y axis (FIG. 7a), the skew bending causes a rototranslation of the respective intermediate portion 5b (FIG. 7b) and a translation of the central portion 5c in the direction of the Z axis. Due to the skew bending, therefore, the displacement in plane (here, along the Y axis) caused by the actuator 3 to the two end portions 5a of the motion conversion elastic element 5 is transformed into an out-of-plane displacement of the motion transmission elastic element 46, and therefore of the platform 2 (in the condition of FIGS. 7a-7c, for example, corresponding to a roll movement of the platform 2).

In the device 1, the actuators 3 of each of the first and second pairs of actuators 3a, 3b may be driven in a concordant manner or in a discordant manner. Furthermore, only the actuators 3 of one pair may be operated, while the actuators 3 of the other pair are not operated. Conversely, all the actuators 3 may be operated simultaneously: for example, the actuators 3 of each of the first and second pairs of actuators 3a, 3b may be driven simultaneously in a discordant manner; or a mixed driving wherein the actuators 3 of a pair are driven in a concordant manner and the actuators 3 of the other pair are driven in a discordant manner is possible.

The term “concordant” means that, in each of the first and second pairs of actuators 3a, 3b, both actuators 3 cause movements in the same direction, i.e., while one actuator 3 of the pair causes movements toward the platform 2 (pushing the corresponding motion conversion elastic element 5), the other actuator 3 of the pair causes movements away from the platform 2 (pulling the corresponding motion conversion elastic element 5). The term “discordant” means that, in each of the first and second pairs of actuators 3a, 3b, the actuators 3 cause movements in opposite directions, i.e., both actuators 3 cause movements toward the platform 2 or both actuators 3 cause movements away from the platform 2.

According to what has been previously described regarding the motion conversion elastic elements 5 of each connection structure 4, in the device 1: a concordant driving of only the actuators 3 of the first pair of actuators 3a causes pure roll movements of the platform 2 (around the X axis), so that a corresponding coupling portion 6 achieves a higher height, with respect to the substrate 1a, than the opposite coupling portion 6 along the Y axis; a concordant driving of only the actuators 3 of the second pair of actuators 3b causes pure pitch movements of the platform 2 (around the Y axis), so that a corresponding coupling portion 6 achieves a higher height, with respect to the substrate 1a, than the opposite coupling portion 6 along the X axis; a discordant driving of the actuators 3 of each of the first and second pairs 3a, 3b causes out-of-plane translation movements of the platform 2, so that all the coupling portions 6 achieve, for example, the same height with respect to the substrate 1a. Furthermore, simultaneous operations of the actuators 3, wherein the actuators 3 of each of the first and second pairs of actuators 3a, 3b are driven in a concordant manner, cause combined roll and pitch movements of the platform 2 (for example, with a rotation axis which forms an angle of 45° with respect to the X axis and the Y axis).

The actuators 3 of the device 1 may statically maintain the platform 2 in a condition different from that of rest shown in FIG. 1, according to the possible movements described, as long as the corresponding actuators 3 are suitably biased. Furthermore, all the movements of the platform 2 imparted by the actuators 3 are reversible by respective reverse operations of the actuators 3.

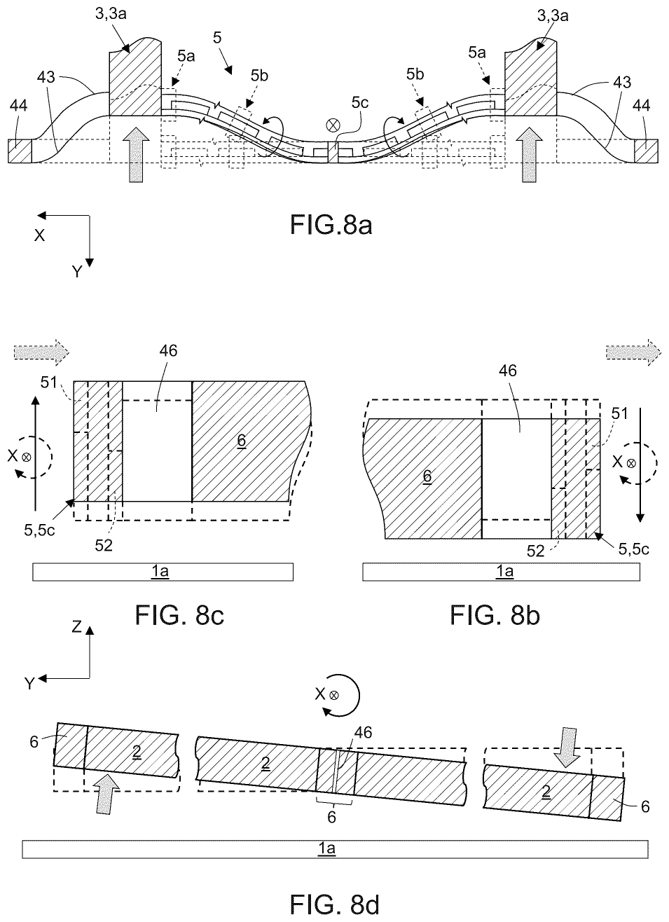

With reference to FIGS. 8a-8d, the actuator 3 of the first pair of actuators 3a shown in FIG. 4 and the corresponding motion conversion elastic element 5 are shown, for example, when a pure roll movement is desired to be imparted to the platform 2. In detail, as shown in FIG. 8a, the actuator 3 of the first pair of actuators 3a causes movements, for example, away from the platform 2, pulling the two end portions 5a of the motion conversion elastic element 5, which translate in plane along the Y axis (in negative direction); the second elastic elements 43 of the corresponding pair bend in plane following the movement of the actuator 3. Simultaneously, as previously explained, each intermediate portion 5b of the motion conversion elastic element 5 is subject to torsion and rotates around the X axis (in addition to translating along the Y axis) and the central portion 5c translates out of plane along the Z axis (downwards).

Then, as shown in FIG. 8b, the motion transmission elastic element 46 follows the movement of the central portion 5c of the motion conversion elastic element 5, transmitting a push along the Z axis downward to the corresponding coupling portion 6 of the platform 2; the corresponding first elastic elements 41 (not shown in FIGS. 8a-8d) allow the movement of the coupling portion 6, bending downward. The coupling portion 6 opposite (along the Y axis) to that shown in FIG. 8b simultaneously receives a push along the Z axis upward from the corresponding motion conversion elastic element 5, due to a concordant driving of the actuators 3 of the first pair of actuators 3a (FIG. 8c). FIG. 8d also shows the overall roll movement of the platform 2: the motion transmission elastic elements 46 of the second pair of connection structures 4b (one shown in FIG. 8d) are configured to twist—without bending out of plane—thus allowing the rotation around the X axis, functioning as constraints.

The same considerations may be applied for the pure pitch movement of the platform 2, replacing the actuator 3 of the first pair of actuators 3a and the corresponding motion conversion elastic element 5 of the connection structure 4 of the first pair of connection structures 4a of FIG. 8a with an actuator 3 of the second pair of actuators 3b and the corresponding motion conversion elastic element 5 of the connection structure 4 of the second pair of connection structures 4b.

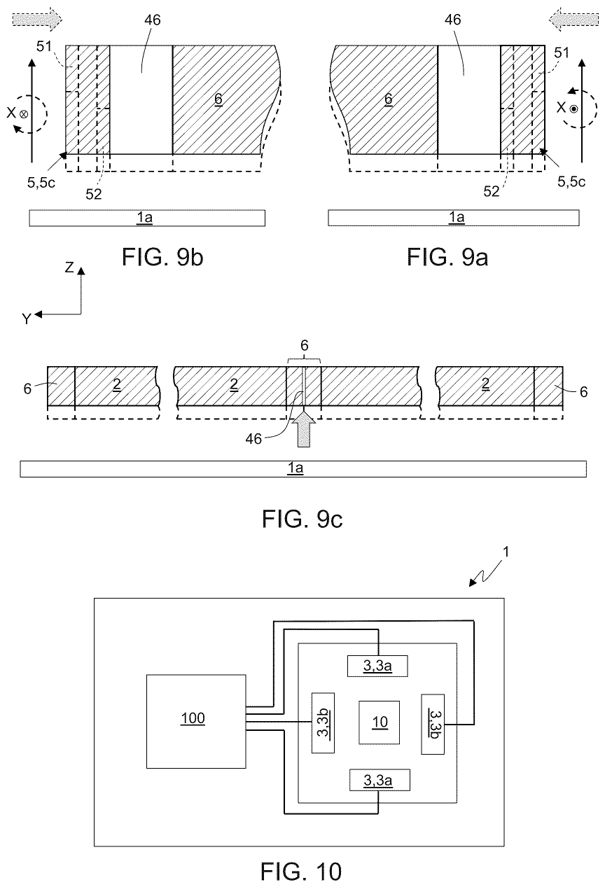

FIGS. 9a-9c show an out-of-plane translation, along the Z axis, of the platform 2 in the device 1. As anticipated, the actuators 3 of each of the first and second pairs 3a, 3b are driven in a discordant manner to cause movements, for example, toward the platform 2, giving rise to a push action of the two end portions 5a of respective motion conversion elastic elements 5. FIGS. 9a and 9b show only portions of the motion conversion elastic elements 5 corresponding to the first pair of connection structures 4a, but the same considerations apply to the motion conversion elastic elements 5 corresponding to the second pair of connection structures 4b, replacing the X axis with the Y axis.

In this case, each intermediate portion 5b of a motion conversion elastic element 5 rotates around the X axis clockwise (in addition to translating along the Y axis), while each intermediate portion 5b of the opposite motion conversion elastic element 5 rotates around the X axis counterclockwise (in addition to translating along the Y axis); simultaneously, the respective central portions 5c of the motion conversion elastic elements 5 translate along the Z axis, both upward (FIGS. 9a and 9b). Then, the corresponding motion transmission elastic elements 46 follow the movement of the central portions 5c, transmitting an upward push to both respective coupling portions 6 of the platform 2, which are opposite along the Y axis; each pair of first elastic elements 41 (not shown in FIGS. 9a-9c) allows the movement of the respective coupling portion 6, bending upward. FIG. 9c shows the overall out-of-plane translation movement of the platform 2.

With reference to FIG. 10, the device 1 further comprises a control unit 100 coupled to the actuators 3. The control unit 100 is configured to provide control signals useful for driving the actuators 3 of each of the first and second pairs of actuators 3a, 3b according to what has been previously described and therefore, ultimately, for carrying out the desired positioning correction of the image sensor 10. In particular, the signals generated by the control unit 100 and intended for the actuators 3 of each pair may be such as to cause concordant and/or discordant driving and may be of the same amplitude or of different amplitudes.

The stabilizer MEMS device allows for an overall improvement in performance in terms of speed and accuracy of compensation for image blur conditions. Thanks to the use of motion conversion elastic elements, linear actuators may be used that cause in-plane movements to obtain a resulting out-of-plane actuation. Such actuators, for example of an electrostatic type, are characterized by capacitance values dependent on a single coordinate (here, X or Y) and therefore intrinsically have excursion ranges that are wider and have more linear dynamics compared to types of actuators comprising structures and elements that are out of plane and/or operated directly for out-of-plane movements. Furthermore, the stabilizer MEMS device significantly reduces production costs, energy consumption of the image sensor movement, and overall dimensions as only planar structures are used. A further advantage is represented by the fact that, while using in-plane actuators, out-of-plane translations (along the Z axis) may be generated, thus also implementing image focus functions, for example in the presence of zoom optical systems and/or for the correction of possible aberrations.

Finally, it is clear that modifications and variations may be made to what has been described and illustrated herein without departing from the scope of this disclosure, as defined in the attached claims.

For example, different types of in-plane actuators may be used for the stabilizer MEMS device compared to those comprising comb electrodes, obtaining the same effects and advantages described.

The platform may have different shapes from that presented and may be connected to the motion conversion elastic elements in a different manner from that described; for example, the coupling portions of the platform may have a different profile from that shown.

One or more combinations of the movements previously described may be imparted to the platform; for example, the actuators may be driven so that the platform performs both an out-of-plane translation (along the Z axis) and a roll, pitch, or combination of roll and pitch movement.

1. A microelectromechanical device, comprising:
a substrate;
a platform that is suspended and movable with respect to the substrate;
actuators arranged on the substrate around the platform, each actuator coupled to a coupling portion of the platform, wherein the actuators have respective actuation axes parallel to the substrate and perpendicular to each other; and
connection structures, wherein each connection structure couples one of the actuators with the platform and comprises a motion conversion elastic element interposed between that actuator and the platform;
wherein each motion conversion elastic element is configured to convert movements of its associated actuator along its respective actuation axis into movements of the corresponding coupling portion of the platform along directions transverse to the substrate.

2. The microelectromechanical device according to claim 1, wherein: the platform has a planar shape parallel to the substrate and comprises pairs of two-by-two parallel sides; and each coupling portion protrudes from one of the sides of the platform, in a substantially central position, toward its associated actuator.

3. The microelectromechanical device according to claim 1,
wherein each motion conversion elastic element comprises a central portion dividing the motion conversion elastic element into two equal sides, each side comprising an end portion and an intermediate portion;
wherein the end portions are opposite to each other with respect to the central portion, and each intermediate portion is disposed between the central portion and its associated end portion; and
wherein a translation of the end portions parallel to the substrate corresponds to a rototranslation of the intermediate portions parallel to a plane perpendicular to the substrate, and a translation of the central portion perpendicular to the substrate.

4. The microelectromechanical device according to claim 3, wherein both end portions of each motion conversion elastic element are connected to its associated actuator; and the central portion is connected to its associated platform coupling portion by a motion transmission elastic element.

5. The microelectromechanical device according to claim 4, wherein each motion transmission elastic element is configured to transmit a translation perpendicular to the substrate to its associated coupling portion, is defined by a flat plate perpendicular to the substrate, and is configured to twist.

6. The microelectromechanical device according to claim 1,
wherein each motion conversion elastic element comprises: a first elastic body; a second elastic body; and a plurality of transverse elements;
wherein the first and second elastic bodies are defined by flat rectangular plates, perpendicular to the substrate and offset from each other along both a direction parallel to the substrate, and a direction perpendicular to the substrate, such that the second elastic body is at a lower height relative to the substrate than the first elastic body; and
wherein the transverse elements are defined by flat rectangular plates perpendicular to the substrate, uniformly spaced from each other, and have first sides connected to the first elastic body and second sides, opposite to the first sides, connected to the second elastic body.

7. The microelectromechanical device according to claim 1, wherein the actuators are organized in: a first pair of actuators having a first actuation axis parallel to the substrate; and a second pair of actuators having a second actuation axis parallel to the substrate and perpendicular to the first actuation axis.

8. The microelectromechanical device according to claim 7, comprising a control unit coupled to the actuators and configured to drive the actuators so that the platform performs at least one of the following movements or combination of movements: rotation around the first actuation axis; rotation around the second actuation axis; and translation parallel to a third actuation axis perpendicular to the substrate.

9. The microelectromechanical device according to claim 7, comprising a control unit coupled to the actuators and configured to drive the actuators so that the platform performs at least one of the following movements or combination of movements: roll; pitch; and out-of-plane translation.

10. The microelectromechanical device according to claim 8, wherein the control unit is configured to drive the actuators of each of the first and second pairs of actuators in either a concordant manner or a discordant manner.

11. The microelectromechanical device according to claim 10, wherein each motion conversion elastic element is coupled to its associated actuator and to the platform so that:
concordant driving of the first pair of actuators causes roll movements of the platform;
concordant driving of the second pair of actuators causes pitch movements of the platform; and
discordant driving of both the first and second pairs of actuators causes out-of-plane translation movements of the platform.

12. The microelectromechanical device according to claim 10, wherein each motion conversion elastic element is coupled to its associated actuator and to the platform so that concordant driving of both the first and second pairs of actuators causes combined roll and pitch movements of the platform.

13. The microelectromechanical device according to claim 7,
wherein the platform comprises a pair of sides parallel to the first actuation axis and a pair of sides parallel to the second actuation axis; and
wherein the motion conversion elastic elements associated with the first pair of actuators are arranged parallel to the second actuation axis; and the motion conversion elastic elements associated with the second pair of actuators are arranged parallel to the first actuation axis.

14. The microelectromechanical device according to claim 1, wherein each connection structure further comprises first elastic elements, first anchors fixed to the substrate, second elastic elements, and second anchors fixed to the substrate;
wherein the first elastic elements and first anchors of each connection structure maintain the platform suspended with respect to the substrate; and
wherein the second elastic elements and second anchors of each connection structure allow movement of the associated actuator.

15. The microelectromechanical device according to claim 14, wherein the first anchors of each connection structure are arranged on opposite sides of the associated coupling portion of the platform;
wherein each first elastic element connects one of the first anchors to the associated coupling portion and is yielding parallel to a direction perpendicular to the substrate;
wherein the second anchors of each connection structure are arranged on opposite sides of the associated actuator; and
wherein each second elastic element connects one of the second anchors to the associated actuator and is yielding parallel to the substrate.

16. The microelectromechanical device according to claim 1, wherein the actuators are electrostatic linear actuators.

17. A method of operating a microelectromechanical device comprising a platform suspended over a substrate and coupled to four actuators arranged around the platform, the method comprising:
providing control signals to drive the actuators, wherein the actuators are arranged in:
a first pair having a first actuation axis parallel to the substrate, and
a second pair having a second actuation axis parallel to the substrate and perpendicular to the first actuation axis;
converting in-plane movements of the actuators into out-of-plane movements of the platform using motion conversion elastic elements, wherein each motion conversion elastic element is coupled between one of the actuators and the platform; and
stabilizing an image sensor mounted on the platform by selectively driving the actuators to perform at least one of:
roll movements of the platform by concordantly driving the first pair of actuators,
pitch movements of the platform by concordantly driving the second pair of actuators, or
out-of-plane translation movements of the platform by discordantly driving both pairs of actuators.

18. The method according to claim 17, wherein:
concordantly driving comprises driving one actuator of a pair to move toward the platform while driving the other actuator of the pair to move away from the platform; and
discordantly driving comprises driving both actuators of a pair to move either toward or away from the platform.

19. The method according to claim 17, further comprising:
performing combined roll and pitch movements of the platform by simultaneously driving both pairs of actuators in a concordant manner; and
maintaining the platform in a static position different from a rest position by continuously providing corresponding control signals to the actuators.

20. The method according to claim 17, wherein converting in-plane movements comprises:
translating end portions of each motion conversion elastic element parallel to the substrate;
causing rototranslation of intermediate portions of each motion conversion elastic element parallel to a plane perpendicular to the substrate; and
translating a central portion of each motion conversion elastic element perpendicular to the substrate.

21. The method according to claim 17, further comprising:
receiving image blur condition data indicative of image blur conditions of the image sensor;
generating control signals based on the image blur condition data; and
operating the actuators in a closed-loop system to compensate for the image blur conditions.
